(19) United States
(12) Patent Application Publication
(10) Pub. No.: US 2010/0019226 A1
(43) Pub. Date: Jan. 28, 2010

(54) SEMICONDUCTOR SENSOR DEVICE, DIAGNOSTIC INSTRUMENT COMPRISING SUCH A DEVICE AND METHOD OF MANUFACTURING SUCH A DEVICE

(75) Inventors: Meriman Nicoletta Kahya, Eindhoven (NL); Erik Petrus Antonius Maria Bakkers, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/441,575

(22) PCT Filed: Sep. 17, 2007
(86) PCT No.: PCT/IB2007/053742

§ 371 Date: Mar. 17, 2009

(30) Foreign Application Priority Data
Sep. 22, 2006 (EP) 06121117.3

(51) Int. Cl. H01L 29/786; H01L 21/02

(52) U.S. Cl. 257/24; 438/49; 257/E21.002; 257/192; 257/253; 257/E29.168; 257/E29.273; 977/938; 977/957

(57) ABSTRACT

The invention relates to a semiconductor sensor device (10) for sensing a substance comprising at least one nanowire (11) which is formed on a surface of a semiconductor body (12) and which is connected at a first end to a first electrically conducting connection region (13) and at a second end to’ a second electrically conducting connection region (14) while a fluid (20) comprising a substance (30) to be sensed can flow along the nanowire (11) and the substance (30) to be sensed can influence’ the electrical properties of the nanowire (11), wherein the nanowire (11) comprises viewed in a longitudinal direction subsequently a first semiconductor subregion (1) comprising a first semiconductor material and a second semiconductor subregion (2) comprising a second semiconductor material different from the first semiconductor material. According to the invention’ the first semiconductor material comprises a IV element material and the second semiconductor material comprises a III-V compound. Due to difference in surface chemistry between subregions 1,2 a substance (30) like an antibody to which a protein signaling a disease can be bonded can be more selectively attached to the desired first region (1).

### FIELD OF THE INVENTION

The invention relates to a semiconductor sensor device for sensing a substance comprising at least one mesa-shaped semiconductor region which are formed on a surface of a semiconductor body and which is connected at a first end to a first electrically conducting connection region and at a second end to a second electrically conducting connection region while a fluid comprising a substance to be sensed can flow along the mesa-shaped semiconductor region and the substance to be sensed can influence the electrical properties of the mesa-shaped semiconductor region, wherein the mesa-shaped semiconductor region comprises viewed in the longitudinal direction subsequently a first semiconductor subregion comprising a first semiconductor material and a second semiconductor subregion comprising a second semiconductor material different from the first semiconductor material. Mesa-shaped of a region here means that the region forms a protrusion on the surface of the semiconductor body. The invention also relates to a diagnosis instrument comprising such a sensor device and to a method of manufacturing such a semiconductor sensor device.

Such a device is very suitable for detecting chemical and/or biochemical substances. In the latter case it can e.g. be used for detecting biomolecules like antigen/antibody bindings, biomolecules and others with a high sensitivity and reproducibility, and thus it can be used advantageously in protein and gene analysis, disease diagnostics and the like. Its sensitivity is particularly high in case the mesa-shaped semiconductor region comprises a nano-wire. Here with a nano wire a body is intended having at least one lateral dimension between 1 and 100 nm and more in particular between 10 and 50 nm. Preferably a nano-wire has dimensions in two lateral directions that are in the said ranges. With such a device the detection of simpler molecules like chemical substances that are volatile or dissolved in a liquid is also possible, e.g. by introduction by the substance of a charge into a nano-wire of which the conductivity is thus changed.

### BACKGROUND OF THE INVENTION

A device as mentioned in the opening paragraph is known from the United States Patent that has been published under number U.S. Pat. No. 6,882,051 on Apr. 19, 2005. In this document, heterojunction nano-wires are disclosed for use in a chemical sensor. See column 35 line 5. In an example of a heterojunction nano-wire, the latter comprises alternating subregions of Silicon (Si) and Germanium (Ge). See FIG. 3 and the corresponding parts of the description. In other example of a heterojunction nano-wire, the latter comprises alternating layers of Galliumarsenide (GaAs) and Galliumantimonide (GaSb). See FIG. 17 and the corresponding part of the description.

A disadvantage of such a device is that its sensitivity is not high enough for certain application. In particular in the medical field detection of a biochemical compound, in particular a biomolecule, is desired already at a very low concentration of such a compound or molecule. This, e.g. for detecting a disease, like an infection, at a very early stage in order to act in a prophylactic manner as much as possible. This requires a sensor device with an extremely high sensitivity.

### SUMMARY OF THE INVENTION

It is therefore an object of the present invention to avoid the above drawback and to provide a semiconductor sensor device, which is suitable for use in the medical field and which possesses a very high sensitivity for the substance to be detected.

To achieve this, a semiconductor sensor device of the type described in the opening paragraph is characterized in that the first subregion comprises a IV element material and the second subregion comprises a III-V compound. It is to be noted that a IV element material means a material of an element of column IV of the periodic system of elements including mixed crystals of different elements of said column. It is to be noted that a III-V compound means a compound of an element of column III and an element of column V of the periodic system of elements including mixed crystals of such compounds. Mixed crystals can be binary, ternary and so on.

The present invention is based on the following recognitions. Firstly, the invention is based on the recognition that IV element surfaces and III-V surface have a different surface chemistry. The latter includes a possible surface reconstruction and/or the involvement of oxygen atoms that may be present as a native oxide, e.g. on the surface of silicon. Such a different surface chemistry is particularly suitable for increasing the sensitivity of a sensor device according to the invention. In this way, a substance to be detected can more readily stick to the free outer surface of the IV element subregion than to the free outer surface of the III-V subregion. In this way the sensitivity of the sensor can be increased. The latter may be effected by the native outer surfaces of the subregions themselves but said surfaces can also be treated differently using said different surface chemistry in order to increase the sensitivity. Thus, the surface of the IV element subregion may be treated such that its sticking capability is increased and/or the surface of the III-V compound subregion may be treated such that its sticking capability is decreased.

Secondly, the invention is based on the recognition that the use of a heterojunction of Si and a III-V compound is not necessarily hampered by the large mismatch usually involved with such a combination of materials. A large mismatch may be avoided or made minimal by using in particular well selected III-V compounds or mixed crystals of such compounds. Moreover, the highest sensitivity is obtained in particular if a nano-wire is used as the mesa-shaped semiconductor region and said nano-wire forms a part of a single-electron transistor. This implies that the first (silicon) subregion forms a quantum dot and thus is very thin viewed in the longitudinal direction of the nano-wire. Moreover in a nano-wire also the lateral dimensions of a subregion are very limited. Thus, the strain induced by a given mismatch between various subregions is very small and does not lead to problems like lifetime reduction due to the creation of dislocations.

In a first preferred embodiment of a semiconductor sensor device according to the invention the mesa-shaped semiconductor region comprises a third subregion bordering the first subregion at a side opposite to the second subregion and comprising a third semiconductor material that comprises a III-V compound, preferably the same III-V compound as the second subregion. Such a device is very suitable for functioning as a (part of a) single-electron transistor since the latter is extremely sensitive for a charge induced in the channel region.

Preferably the second and third subregion comprises a material having a higher bandgap than the bandgap of the material of the first subregion and preferably comprise GaP while the first subregion preferably comprises Si. In such a heterojunction improves the injection efficiency of either electrons or holes, depending on the relative magnitude of the bandgap energy of the two sides of a pn junction in or at the first subregion. Inter-band tunneling can be suppressed by the barrier between the first and bordering subregions. In this way a high leakage current, i.e. a high off current is prevented.

The off-set between the valence band and conduction band can be tuned by providing a step or grading in the composition of the second subregion. In a suitable structure for that purpose, the silicon subregion may be bordered by a GaP part of the bordering subregions, the latter being bordered by a GaAs part. A step function has the advantage that the control requirements for the growth conditions is less strict than in case of grading. In this way a barrier on one side of the first subregion may be selectively reduced.

In another preferred embodiment of a semiconductor sensor device according to the invention, a free outer surface of the first subregion is functionalized so as to increase the probability that the substance to be detected sticks to said free outer surface. In this way the sensitivity of the sensor is further increased. A suitable form of functionalization comprises the formation on said free outer surface of the first subregion of a self-assembled monolayer of a compound that attracts the substance to be detected. Such a mono-layer can be formed e.g. by a treatment with an amino-alkyl-carbon acid. The amino group is adsorbed on the Si/SiOx surface of the first subregion, while the alkyl chains are oriented in parallel with their length direction substantially parallel to the surface of the first subregion. On top of said chains a plane of carboxyl groups is formed that attracts e.g. the lower part of a Y-shaped antibody that will bind to a protein. The latter being an indication of a disease like an infection or cancer, e.g. prostate cancer. In this way a very high sensitivity is obtained for detecting such a protein.

Preferably a free outer surface of the other than the first subregions, i.e. the second and third subregions, is functionalized so as to decrease the probability that the substance to be detected sticks to said free outer surface. Again, this may be obtained by a functionalization comprising the formation on said free outer surface of a self-assembled monolayer of a compound that repels the substance to be detected. A suitable compound for these purposes is a PEG (=poly-ethylene-glycol) polymer. On top thereof a “plane” of ball-shaped alkyl groups is formed that repels the above mentioned antibody. This also increases the sensitivity. Advantageously both treatments may be combined for maximal sensitivity.

As mentioned before the at least one mesa-shaped semiconductor region advantageously comprises a nano-wire, preferably a plurality of mutually parallel nano-wires positioned on the surface of the semiconductor body while their length direction runs perpendicular to said surface. A mesa-shaped semiconductor region or nano-wire preferably form a part of a normally off element such as a transistor, preferably a single electron transistor.

In an important embodiment the sensor device is suitable for detecting a biomolecules such as an antibody that will bound to a certain protein. The invention further comprises a diagnostic instrument comprising a semiconductor sensor device according to the invention.

A method of manufacturing a semiconductor sensor device for sensing a substance comprising at least one mesa-shaped semiconductor region which is formed on a surface of a semiconductor body and which is connected at a first end to a first electrically conducting connection region and at a second end to a second electrically conducting connection region while a fluid comprising a substance to be sensed can flow along the mesa-shaped semiconductor region and the substance to be sensed can influence the electrical properties of the mesa-shaped semiconductor region, wherein the mesa-shaped semiconductor region is formed with viewed in the longitudinal direction subsequently a first semiconductor subregion comprising a first semiconductor material and a second semiconductor subregion comprising a second semiconductor material different from the first semiconductor region, is according to the invention, characterized in that the for the first semiconductor material a IV element material is chosen and for the second semiconductor material a III-V compound is selected.

In a first preferred embodiment of a method according to the invention a free outer surface of the first subregion is functionalized so as to increase the probability that the substance to be detected sticks to said free outer surface by forming on said surface a self-assembled monolayer of a compound that attracts the substance to be detected.

In a second preferred embodiment a free outer surface of the other than the first subregions is functionalized so as to decrease the probability that the substance to be detected sticks to said free outer surface by forming on said surface a self-assembled monolayer of a compound that repels the substance to be detected.

Preferably, after formation of the self-assembled monolayer(s) the device is washed to remove the molecules of the compound forming the self-assembled monolayer(s) that accidentally sticks to another part of the outer surface than where the monolayer(s) are formed.

### BRIEF DESCRIPTION OF THE DRAWINGS

These and other aspects of the invention will be apparent from and elucidated with reference to the embodiments described hereinafter, to be read in conjunction with the drawing, in which

FIG. 1 shows a cross-section perpendicular to the thickness direction of a first embodiment of a semiconductor sensor device according to the invention.

FIGS. 2 and 3 show various bandgap profiles for the current blocked situation (a) and for the current on situation (b) for various compositional configurations of the sensor device of FIG. 1,

FIG. 4 shows a cross-section perpendicular to the thickness direction of a second embodiment of a semiconductor sensor device according to the invention,

FIGS. 5 through 7 are sectional views of a part of the semiconductor sensor device of FIG. 4 at various stages in its manufacture by means of a first method in accordance with the invention, and

FIGS. 8 through 10 are sectional views of a part of the semiconductor sensor device of FIG. 4 at various stages in its manufacture by means of a second method in accordance with the invention

### DETAILED DESCRIPTION OF THE PREFERRED EMBODIMENTS

The Figures are diagrammatic and not drawn to scale, the dimensions in the thickness direction being particularly exaggerated for greater clarity. Corresponding parts are generally given the same reference numerals and the same hatching in the various Figures.

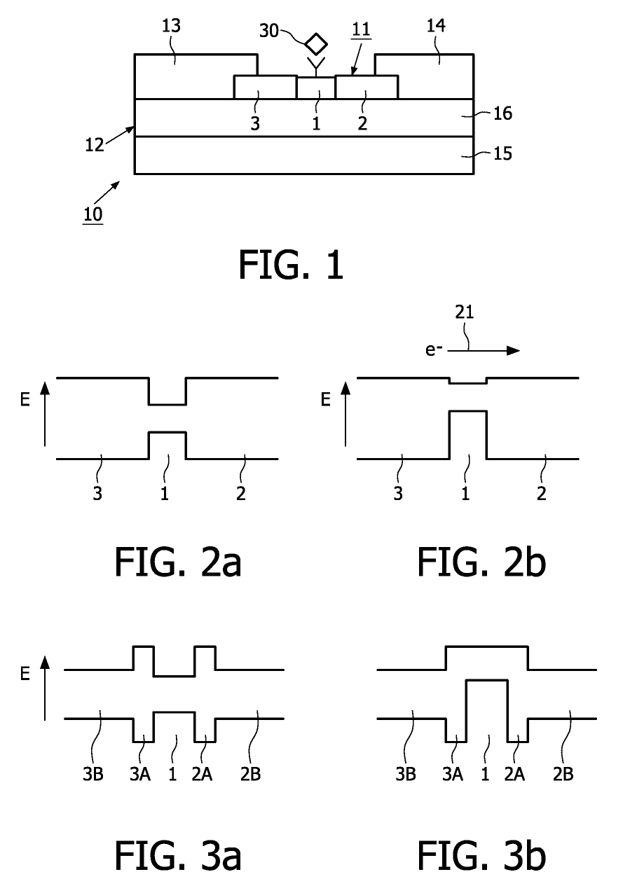

FIG. 1 shows a cross-section perpendicular to the thickness direction of a first embodiment of a semiconductor sensor device according to the invention. The device 10 comprises in this example a silicon substrate 15 that is provided with a silicon dioxide layer 16. Thereon a nano-wire 11 is positioned with its length direction parallel to the surface of the semiconductor body 12. The nano-wire 11 comprises three sections 1,2,3 with different compositions. A first section 1 comprises lowly doped p-type silicon forming a quantum dot region 1 between further sections 2,3 each comprising GaP. These sections 2,3 are provided with (semi)conducting regions 13,14 of highly n-type doped polycrystalline silicon forming the source and drain regions of a field effect transistor, here a single-electron transistor, of which the channel region lies within the nano-wire 11. Source and drain regions are provided with a metallization and connection conductors that are not shown in the drawing and thus form at the same time connection regions 13,14 for the transistor. An antibody 30 coupled to a protein signaling a certain disease and flowing in a blood sample along the nano-wire 11 will after landing on and sticking to the silicon region 1 induce a charge into the channel region of the single electron transistor. Said charge increases a large change in the conductance of the transistor, which can be signaled. Due to the different materials of on the one hand subregion 1 and on the other hand subregions 2,3 the sticking probability of substance 30 may be larger on the free surface of subregion 1, comprising a Si/SiOx surface than on the free surface of regions 2,3 comprising a ITT-V material. In this way the sensitivity of the sensor device 10 is increased.

FIGS. 2 and 3 show various bandgap (E) profiles for the current blocked situation (a) and for the current on situation (b) for various compositional configurations of the sensor device of FIG. 1. In the current blocked situation (see FIG. 2a) the regions 2,3 of GaP form a double heterojunction with silicon region 1. In the current on situation (see FIG. 2b) an electron current can flow as indicated by arrow 21. GaP not only has a relatively high bandgap E compared to silicon but also a relatively low lattice mismatch. The latter implies that only little strain is induced in the device 10 by the presence of these GaP regions 2,3. FIG. 3 shows for the same conditions the bandgap E for the situation in which subregions 2,3 comprise a first part 2A,3A comprising GaP (as in FIG. 2) and a second, more remote, part 2B,3B comprising GaAs. As shown in FIG. 3b, the barrier height between the silicon region 1 and GaP regions 2A,3A can be largely removed thus easing transport of charge carriers comprising electrons through the structure in the current on situation.

The device 10 of this example may be e.g. manufactured by positioning a nano-wire 11 obtained by VLS (=Vapor Liquid Solid) epitaxy on the surface of an oxidized silicon substrate 15. Subsequently, a part of the nano-wire 11 is masked and polycrystalline regions 13,14 are formed by deposition and patterning. Hereinafter the mask used on the nano-wire 11 is again removed. Another way of manufacturing such a sensor device is by using (selective) epitaxial processes to form the various subregions followed by photolithography and etching to form the mesa/nanowire.

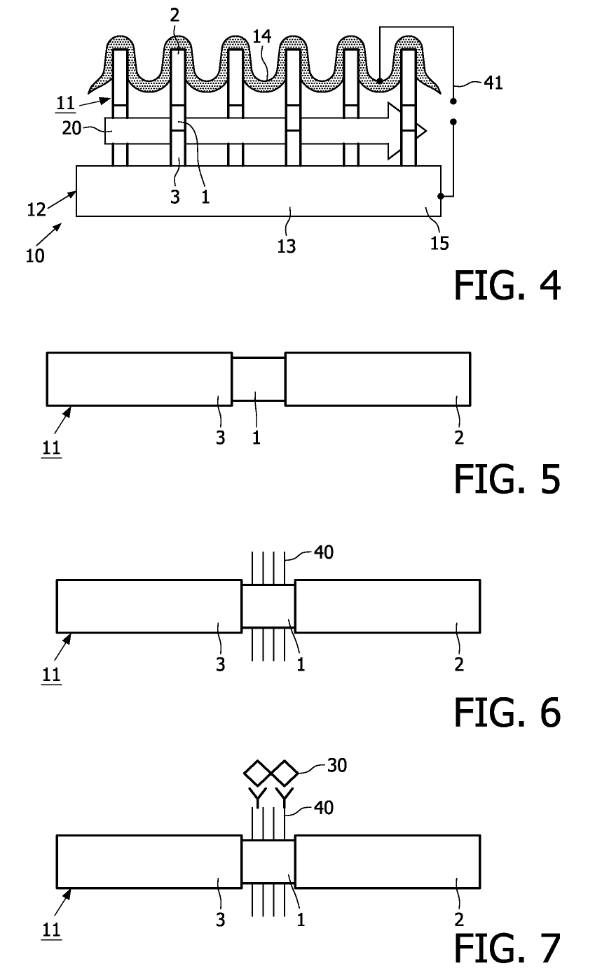

FIG. 4 shows a cross-section perpendicular to the thickness direction of a second embodiment of a semiconductor sensor device according to the invention. The sensor device 10 of this example comprises a plurality of nano-wires 11 which are grown by the above mentioned VLS epitaxy technique on a silicon substrate 15 that at the same time functions as a first connection region 13. The substrate is covered with an insulating layer between the nano-wires 11 which is not shown in the drawing. The other sides of the nano-wires 1 is provided with a metallization that forms a second connection region 14 that with connection region 13 forms a part of a control and measuring circuit 41. Each nano-wire 11 again comprises three sections 1,2, 3 comprising—as in the previous example, respectively GaP, Si and GaP. In this example as in the previous example the surface is treated with a liquid comprising antibodies. A sample flow 20 of e.g. blood containing protein molecules that signal a disease may pass along the space between the plurality of nano-wires 11, each forming again a single-electron field effect transistor. Thank to the latter and thanks to the use of a plurality of nano-wires 11, the sensor 10 of this example is extremely sensitive for e.g. a protein that can be detected after it binds to the antibodies bound to a protein. The sensitivity is further enhanced by a surface treatment of the free outer surface of the nano-wires 11 as will be described below.

FIGS. 5 through 7 are sectional views of a part of the semiconductor sensor device of FIG. 4 at various stages in its manufacture by means of a first method in accordance with the invention. In this modification, first nano-wires 11 are grown on a substrate as discussed above and the connection regions 13,14 are provided. One nano-wire of the device at this stage is shown in FIG. 5 in a state after rotation over 90 degrees compared to FIG. 4. Next (see FIG. 6) a self-assembled monolayer 40 is selectively formed on the free outer Si/SiOx surface of subregion 1. In this example said monolayer 40 is formed by treatment with an amino-alkyl-carbon acid, of which the alkyl group contains 12 to 16 carbon atoms. Subsequently the sensor 10 is washed with a phosphate solution at pH about equal to 11. In this way, rare molecules of the compound used for forming monolayer 40 that have become attached to the outer surface of regions 2,3 comprising GaP can be washed away, leaving the latter surface clean. In this way (see FIG. 7) the probability of sticking of an antibody 30 to which a protein signaling a disease will be bound, to the sensor device 10 at region 1 is highly increased. In this way, the sensor 10 becomes extremely sensitive for detecting such antibodies 30 and proteins bound thereto.

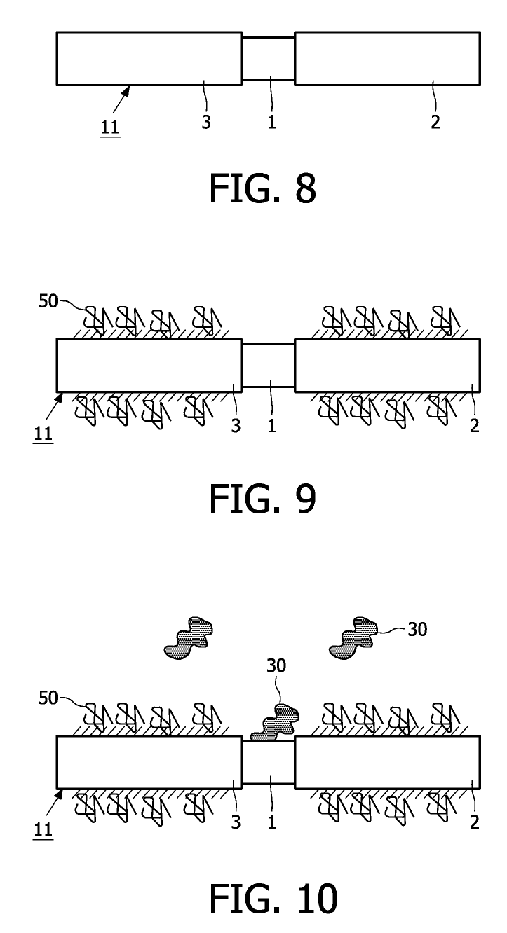

FIGS. 8 through 10 are sectional views of a part of the semiconductor sensor device of FIG. 4 at various stages in its manufacture by means of a second method in accordance with the invention.

FIGS. 1 through 4 are sectional views of a semiconductor sensor device at various stages in its manufacture by means of a method in accordance with the invention. The manufacturing of the semiconductor sensor device 10 is the same as discussed above for the first modification of the manufacturing of the device of this example. FIG. 8 shows a nano-wire 11 after rotation over 90 degrees in a final stage of its manufacture corresponding to the situation of FIG. 4. Subsequently (see FIG. 9) the surface of the GaP regions 2,3 is selectively provided with a PEG (=Poly Ethylene Glycol) polymer forming a self-assembled monolayer 50 of such a material on said surface. A possible mechanism explaining the functioning of said monolayer 50 is that the presence of outer globular a-polar parts of such a monolayer 50, the sticking probability (see FIG. 10) of an antibody 30 on such a surface is decreased. In this way, the sensitivity of the device 10 is increased since antibodies 30 stick more selectively on region 1.

It is to be noted that the sensitivity of the sensor 10 can be further increased by a combined treatment of both the surface of Si region 1 and GaP regions 2,3 in a manner described above and shown in the FIGS. 5-7 and 8-10 respectively. A preferred order for such combined procedure is to treat the first subregion 1 (here of Si) and the second and third subregions 2,3 (here of GaP) last. Firstly, steric hindrance of the monolayers on the subregions 2,3 to the relatively thin/small first subregion 1 is avoided. Secondly, un-removed contamination of the first subregion by material intended for the second/third regions may be more detrimental than un-removed contamination of the second/third regions by material intended for the first subregion.

It will be obvious that the invention is not limited to the examples described herein, and that within the scope of the invention many variations and modifications are possible to those skilled in the art.

For example it is to be noted that in stead of antibodies also ssDNA (=Single Strand Desoxyribo Nucleic Acid) molecules may advantageously be attached to a surface of the first subregion provided with a monolayer of a suitable compound to enhance selective attachment. A specific complimentary DNA chain that is to be detected, can selectively be bonded to said ssDNA. As in the case of a protein binding to an antibody, the binding of said complimentary DNA to the ssDNA will result in charge redistribution near the surface of the sensor device that then will be detected with high sensitivity.

Furthermore it is noted that various modifications are possible with respect to individual manufacturing steps. For example other deposition techniques can be selected instead of those used in the example.

1. Semiconductor sensor device (10) for sensing a substance comprising at least one mesa-shaped semiconductor region (11) which is formed on a surface of a semiconductor body (12) and which is connected at a first end to a first electrically conducting connection region (13) and at a second end to a second electrically conducting connection region (14) while a fluid (20) comprising a substance (30) to be sensed can flow along the mesa-shaped semiconductor region (11) and the substance (30) to be sensed can influence the electrical properties of the mesa-shaped semiconductor region (11), wherein the mesa-shaped semiconductor region (11) comprises viewed in a longitudinal direction subsequently a first semiconductor subregion (1) comprising a first semiconductor material and a second semiconductor subregion (2) comprising a second semiconductor material different from the first semiconductor material, characterized in that the first semiconductor material comprises a IV element material and the second semiconductor material comprises a III-V compound.

2. Semiconductor sensor device (10) according to claim 1, wherein the mesa-shaped semiconductor region (11) comprises a third subregion (3) bordering the first subregion (1) at a side opposite to the second subregion (2) and comprising a third semiconductor material that comprises a III-V compound, preferably the same III-V compound as the second subregion (2).

3. Semiconductor sensor device (10) according to claim 2, wherein the second and third subregion (2,3) comprises a material having a higher bandgap than the bandgap of the material of the first subregion (1) and preferably comprise GaP while the first subregion (1) preferably comprises Si.

4. Semiconductor sensor device (10) according to claim 2, wherein the second and third subregions (2,3) comprise a first part (2A,3A) bordering the first subregion (1) and comprising a III-V compound with a higher bandgap than the material of the first subregion (1) and a second part (2B,3B) bordering the first part (2A,3A) and comprising a III-V compound with a lower bandgap than the first part (2A,3A) and preferably comprising GaAs.

5. Semiconductor sensor device (10) according to claim 1, wherein a free outer surface of the first subregion (1) is functionalized so as to increase the probability that the substance (30) to be detected sticks to said free outer surface.

6. Semiconductor sensor device (10) according to claim 5, wherein said functionalization comprises the formation on said free outer surface of a self-assembled monolayer (40) of a compound that attracts the substance (30) to be detected.

7. Semiconductor sensor device (10) according to claim 6, wherein the self assembled monolayer (40) is formed by an amino-alkyl-carbon acid, the alkyl group preferably comprising between 12 and 16 carbon atoms.

8. Semiconductor sensor device (10) according to claim 1, wherein a free outer surface of the other than the first subregions (2,3) is functionalized so as to decrease the probability that the substance (30) to be detected sticks to said free outer surface.

9. Semiconductor sensor device (10) according to claim 8, wherein said functionalization comprises the formation on said free outer surface of a self-assembled monolayer (50) of a compound that repels the substance (30) to be detected.

10. Semiconductor sensor device (10) according to claim 9, wherein the self-assembled monolayer (50) is formed by a poly-ethylene-glycol polymer.

11. Semiconductor sensor device (10) according to claim 1, wherein the at least one mesa-shaped semiconductor region (11) comprises a nano-wire (11), preferably a plurality of mutually parallel nano-wires (11) positioned on the surface of the semiconductor body (12) while their length direction runs perpendicular to said surface.

12. Semiconductor sensor device (10) according to claim 1, wherein the mesa-shaped semiconductor region (11) forms a part of a normally off element such as a transistor, preferably a single electron transistor in which the first subregion (1) forms a quantum dot.

13. Semiconductor sensor device (10) according to claim 1, wherein the device (10) is suitable for detecting a biomolecules such as an protein bound to an antibody.

14. Diagnostic instrument comprising a semiconductor sensor device (10) according to claim 1.

15. Method of manufacturing a semiconductor sensor device (10) for sensing a substance (30) comprising at least one mesa-shaped semiconductor region (11) which is formed at a surface of a semiconductor body (12) and which is connected at a first end to a first electrically conducting connection region (13) and at a second end to a second electrically conducting connection region (14) while a fluid (20) comprising a substance (30) to be sensed can flow along the mesa-shaped semiconductor region (11) and the substance (30) to be-sensed can influence the electrical properties of the mesa-shaped semiconductor region (11), wherein the mesa-shaped semiconductor region (11) is formed with viewed in a longitudinal direction subsequently a first semiconductor subregion (1) comprising a first semiconductor material and a second semiconductor subregion (2) comprising a second semiconductor material different from the first semiconductor material, characterized in that the for the first semiconductor material a IV element material is chosen and for the second semiconductor material a III-V compound is selected.

16. Method according to claim 15, wherein a free outer surface of the first subregion (1) is functionalized so as to increase the probability that the substance (30) to be detected sticks to said free outer surface by forming on said surface a self-assembled monolayer (40) of a compound that attracts the substance to be detected.

17. Method according to claim 15, wherein a free outer surface of the other than the first subregions (2,3) is functionalized so as to decrease the probability that the substance (30) to be detected sticks to said free outer surface by forming on said surface a self-assembled monolayer (50) of a compound that repels the substance to be detected.

18. Method according to claim 16, wherein after formation of the self-assembled monolayer (40,50) the device (10) is washed to remove the molecules of the compound that accidentally stick to another part of the outer surface of the mesa-shaped semiconductor region (11) than that where the self-assembled monolayer (40,50) is built.
